(19) United States
(12) Patent Application Publication
(10) Pub. No.: US 2026/0092142 A1
(43) Pub. Date: Apr. 2, 2026

(54) RESIN COMPOSITION, CURED PRODUCT, SCINTILLATOR PANEL, AND INDUCTOR

(71) Applicant: Toray Industries, Inc., Chuo-ku, Tokyo (JP)

(72) Inventors: Hayato NARIKIYO, Otsu-shi, Shiga (JP); Sho MIYAO, Otsu-shi, Shiga (JP); Natsumi OKURA, Otsu-shi, Shiga (JP)

(73) Assignee: Toray Industries, Inc., Chuo-ku, Tokyo (JP)

(21) Appl. No.: 19/113,489

(22) PCT Filed: Aug. 23, 2023
(86) PCT No.: PCT/JP2023/030321

§ 371 Date: Mar. 20, 2025

(30) Foreign Application Priority Data
Sep. 26, 2022 (JP) 2022-152221

(51) Int. Cl. C08G 65/26; C08G 59/40; G03F 7/029; G03F 7/038; G03F 7/075

(52) U.S. Cl. CPC C08G 65/26; C08G 59/40; G03F 7/029; G03F 7/038; G03F 7/075

(57) ABSTRACT

Provided is a resin composition capable of forming a pattern having a high aspect ratio, the resin composition comprising: a (A) resin; an (B) oxetane compound; and a photocationic polymerization initiator, wherein the (A) resin includes a resin having an alkali-soluble group, and wherein the (B) oxetane compound includes a (B-1) compound having four or more oxetanyl groups.

### CROSS REFERENCE TO RELATED APPLICATIONS

This application is the U.S. National Phase of PCT/JP2023/030321, filed Aug. 23, 2023, which claims priority to Japanese Patent Application No. 2022-152221, filed Sep. 26, 2022, the disclosures of these applications being incorporated herein by reference in their entireties for all purposes.

### FIELD OF THE INVENTION

The present invention relates to a resin composition, a cured product, a scintillator panel, and an inductor.

### BACKGROUND OF THE INVENTION

In a medical field, or in industrial applications such as structure inspections and luggage inspections, a radiation detection device employing a digital system, such as a radiation detector of a flat panel type (flat panel detector: FPD), has been used. In the FPD employing an indirect conversion system, a scintillator panel is used for converting X-rays into visible light. The scintillator panel has a phosphor layer (scintillator layer) containing a phosphor such as gadolinium oxysulfide (GOS), and the phosphor emits light due to irradiation with X-rays. The scintillator panel converts information of the X-rays into digital image information through conversion of the light emitted from the scintillator panel into electric signals with use of a sensor (photoelectric conversion layer) having a thin-film transistor (TFT) or a charge-coupled device (CCD). However, the scintillator panel has a problem that the light emitted from the radiation phosphor scatters in the phosphor layer, causing reduction in the sharpness of an image to be obtained.

In view of such circumstances, in order to reduce the influence of the scattering of light, there has been proposed a method of filling a space defined by barrier ribs with a phosphor. Further, as a technology for solving a problem of reduction in brightness due to the presence of the barrier ribs, there has been proposed a scintillator panel comprising: a substrate; barrier ribs formed on the substrate; and a scintillator layer defined by the barrier ribs and having a phosphor, the barrier ribs containing one or more compounds (P) selected from the group consisting of polyimide, polyamide, polyamideimide, and polybenzoxazole (see, for example, Patent Document 1).

Meanwhile, in industrial applications such as food and electronic components, there has been a tendency that, in in-line inspections, the brightness is liable to be reduced over time due to continuous irradiation with high-energy X-rays. To cope with such circumstances, there has been proposed a scintillator panel comprising: a base material; and a scintillator layer containing a phosphor, the scintillator layer containing a binder resin having π-conjugated structure formed of seven or more atoms, the binder resin having a glass transition point of from 30° C. to 430° C., the scintillator layer having a film thickness of from 50 μm to 800 μm (see, for example, Patent Document 2).

### Patent Document

Patent Document 1: WO 2021/200327 A1
Patent Document 2: WO 2022/024860 A1

### SUMMARY OF THE INVENTION

Incidentally, particularly in industrial applications, irradiation with high-energy X-rays requires thickening of the phosphor layer and thinning of the barrier ribs in order to increase the phosphor amount. In view of such a background, barrier ribs having a higher aspect ratio have been demanded. However, resin compositions having hitherto been known have difficulty in forming a pattern of, for example, barrier ribs having a higher aspect ratio that have been demanded in view of such a background.

Thus, in view of such problems of conventional arts, the present invention has an object to provide a resin composition capable of forming a pattern having a high aspect ratio, a cured product, a scintillator panel, and an inductor.

A resin composition according to one aspect of the present invention that solves the problems described above is a resin composition, comprising: a (A) resin; an (B) oxetane compound; and a photocationic polymerization initiator, wherein the (A) resin includes a resin having an alkali-soluble group, and wherein the (B) oxetane compound includes a (B-1) compound having four or more oxetanyl groups.

Moreover, a cured product according to one aspect of the present invention that solves the problems described above is a cured product obtained by curing the resin composition described above.

Further, a scintillator panel according to one aspect of the present invention that solves the problems described above is a scintillator panel, comprising: a substrate; barrier ribs formed on the substrate; and a phosphor layer formed in cells defined by the barrier ribs, wherein the barrier ribs are made of the cured product described above.

Moreover, an inductor according to one aspect of the present invention that solves the problems described above is an inductor comprising an insulation film and a coil, wherein the insulation film is the cured product described above.

### BRIEF DESCRIPTION OF THE DRAWINGS

FIG. 1 is a sectional view schematically illustrating a radiation detector member including a scintillator panel according to one embodiment of the present invention.

FIG. 2 is an enlarged sectional view schematically illustrating a substrate and a barrier rib part of the radiation detector member illustrated in FIG. 1.

FIG. 3 is a sectional view schematically illustrating the structure of an inductor according to one embodiment of the present invention.

### DETAILED DESCRIPTION OF EMBODIMENTS OF THE INVENTION

A resin composition according to one embodiment of the present invention contains a (A) resin, an (B) oxetane compound, and a photocationic polymerization initiator. The (A) resin includes a resin having an alkali-soluble group. The (B) oxetane compound includes a (B-1) compound having four or more oxetanyl groups (hereinafter sometimes simply referred to as “(B-1) oxetane compound”).

The (A) resin exerts an action of keeping the shape of the resin composition and thus improving the processability. The (B) oxetane compound is cured through cationic polymerization. In particular, through selection of the (B-1) compound having four or more oxetanyl groups that is excellent in curability among various oxetane compounds, the resin composition can form a pattern having a high aspect ratio with a high resolution. The resin composition may contain, as the (B) oxetane compound, an oxetane compound having one to three oxetanyl groups together with the (B-1) oxetane compound.

It is preferred that the resin composition according to this embodiment further contain an (C) epoxy compound. Further, the resin composition contains the photocationic polymerization initiator. The (C) epoxy compound exerts an effect of improving adhesion to a base material in the case of forming the resin composition on the base material. When the resin composition contains the photocationic polymerization initiator, irradiation with light causes the photocationic polymerization initiator to generate an acid. As a result, the (B) oxetane compound is polymerized, and the photosensitivity of a negative type that causes the resin composition to be insoluble with respect to a developer liquid is exhibited. In a pattern formation utilizing the photosensitivity of a negative type, an exposed portion that involves photocrosslinking forms a pattern. Thus, a pattern that is excellent in mechanical property can be formed.

### <(A) Resin>

Examples of the resin include an acrylic resin, a styrene-based resin, a phenolic resin, an epoxy resin, polyester, polyvinyl alcohol, polyamide, polyimide, polyamideimide, and polybenzoxazole. Two or more kinds of the resins may be contained as the resin. Among those, the resin is preferably polyamide, polyimide, polyamideimide, or polybenzoxazole. When any of those resins is used as the resin, the resin composition can improve the mechanical property of a cured product to be obtained. Thus, a pattern having a higher aspect ratio can be formed. The resin is more preferably polyimide or polybenzoxazole.

It is preferred that the (A) resin have a weight-average molecular weight of 1,000 or more, more preferably 2,000 or more. Further, it is preferred that the resin have a weight-average molecular weight of 20,000 or less, more preferably 10,000 or less. When the (A) resin has a weight-average molecular weight of 1,000 or more, the resin composition may be improved in film forming property. When the (A) resin has a weight-average molecular weight of 20,000 or less, the resin composition may be improved in the solubility at the time of development. The weight-average molecular weight of the (A) resin in this embodiment is measured by gel permeation chromatography (GPC) and calculated in terms of polystyrene.

In view of the cationic polymerizability, it is preferred that the (A) resin substantially do not have a basic functional group such as an amino group that may be an inhibitory group against the cationic polymerization. When the resin substantially does not have an inhibitory group against the cationic polymerization, the resin composition can enhance the cationic polymerizability and thus form a pattern having a higher aspect ratio. Here, the phrase “substantially do/does not have” means that, specifically, an equivalent of the basic functional group is 1,000 g/eq or more.

The (A) resin includes a resin having an alkali-soluble group. Accordingly, the resin composition can obtain adequate solubility in the case of developing with an alkaline developer liquid. Thus, the contrast between an exposed portion and an unexposed portion can be enhanced. Examples of the alkali-soluble group include a phenolic hydroxyl group, a carboxy group, a silanol group, and a sulfo group. The (A) resin may have two or more kinds of the alkali-soluble groups. Among those, the alkali-soluble group is preferably a phenolic hydroxyl group. Examples of the resin having a phenolic hydroxyl group include polyhydroxyphenyl acrylate, polyhydroxyphenyl methacrylate, and polyparahydroxy styrene, or polyamide, polyimide, polyamideimide, and polybenzoxazole having a phenolic hydroxyl group. The (A) resin may contain a resin having two or more kinds of the phenolic hydroxyl groups.

It is preferred that the polyamide, polyimide, polyamideimide, and polybenzoxazole having a phenolic hydroxyl group have a diamine residue having a phenolic hydroxyl group. Examples of the diamine residue having a phenolic hydroxyl group include residues derived from aromatic diamine such as bis(3-amino-4-hydroxyphenyl)hexafluoropropane, bis(3-amino-4-hydroxyphenyl)sulfone, bis(3-amino-4-hydroxyphenyl)propane, bis(3-amino-4-hydroxyphenyl)methylene, bis(3-amino-4-hydroxyphenyl)ether, bis(3-amino-4-hydroxy)biphenyl, 2,2′-ditrifluoromethyl-5,5′-dihydroxyl-4,4′-diaminobiphenyl, bis(3-amino-4-hydroxyphenyl)fluorene, or 2,2′-bis(trifluoromethyl)-5,5′-dihydroxybenzidine, or a compound obtained by substituting a part of an aromatic ring of those or hydrogen atoms of hydrocarbon with an alkyl group or a fluoroalkyl group having 1 to 10 carbon atoms or with halogen atoms. The polyamide, polyimide, polyamideimide, and polybenzoxazole having a phenolic hydroxyl group may have two or more kinds of diamine residue having phenolic hydroxyl groups. Further, the polyamide, polyimide, polyamideimide, and polybenzoxazole having an alkali-soluble group may further have a diamine residue having no phenolic hydroxyl group.

It is preferred that the content of the (A) resin in the resin composition according to this embodiment be 15 mass %, more preferably 25 mass % or more in a solid content. Further, it is preferred that the content of the (A) resin in the resin composition be 70 mass % or less, more preferably 60 mass % or less in a solid content. When the content of the (A) resin is 15 mass % or more, a cured product obtained by curing the resin composition may be improved in the mechanical property and the thermal property. Meanwhile, when the resin composition contains the (A) resin by 70 mass % or less, the resin composition can suppress a development residue in the case of developing.

### <(B) Oxetane Compound>

The resin composition according to this embodiment contains an (B) oxetane compound. Examples of the (B) oxetane compound include 3-methyl-3-hydroxymethyloxetane, 3-ethyl-3-hydroxymethyloxetane, 2-ethylhexyl(3-ethyl-3-oxetanylmethyl)ether, 2-hydroxyethyl(3-ethyl-3-oxetanylmethyl)ether, 2-hydroxypropyl(3-ethyl-3-oxetanylmethyl)ether, 1,4-bis[(3-ethyl-3-oxetanylmethoxy)methyl]benzene, oxetanylsilsesquioxane, phenol novolac oxetane, and OXT-191 (product name, manufactured by TOAGOSEI CO., LTD.). The resin composition may contain two or more kinds of the (B) oxetane compounds. In this embodiment, a compound having an oxetanyl group is classified as the (B) oxetane compound even when it is a resin or a compound having an epoxy group.

Among those, the resin composition according to this embodiment is characterized in that it contains a (B-1) compound having four or more oxetanyl groups. As mentioned above, through selection of the compound having four or more (B-1) oxetanyl groups excellent in curability as the (B) oxetane compound, the resin composition can form a pattern having a high aspect ratio. A resin composition containing only a compound having less than four oxetanlyl groups as the (B) oxetane compound exhibits insufficient resolution when a high pattern is formed, resulting in insufficient aspect ratio. Examples of the (B-1) oxetane compound include oxetanyl silsesquioxane, phenol novolac oxetane, and OXT-191 (product name, manufactured by TOAGOSEI CO., LTD.). The resin composition may contain two or more kinds of the (B-1) oxetane compounds. The number of oxetanyl groups in one molecule is preferably 7 or more. Accordingly, the resin composition is further improved in curability, and a pattern having a higher aspect ratio can be formed. Meanwhile, the number of oxetanyl groups in one molecule is preferably 20 or less. Accordingly, the resin composition can suppress generation of cracks at the time of patterning. The oxetane compound in which the number of oxetanyl groups in one molecule is 7 or more and 20 or less is, for example, OXT-191 (product name, manufactured by TOAGOSEI CO., LTD.).

It is preferred that the (B-1) compound having four or more oxetanyl groups have the structure as expressed by the following general formula (1).

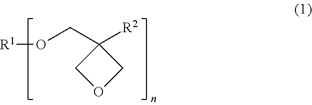

In the general formula (1) given above, R¹ represents an n-valent group having a siloxane bond. R² represents a hydrogen atom or a monovalent organic group having 1 to 6 carbon atoms. “n” represents a range of from 4 to 30, preferably a range of from 7 to 20.

R¹ has a siloxane bond. The siloxane bond undergoes hydrolysis with an alkaline developer liquid, and hence adequate solubility can be obtained in the case of developing with an alkaline developer liquid. Thus, the contrast between the exposed portion and the unexposed portion can be increased. R¹ is preferably silicate or polysilicate.

An organic group constituting R² is preferably, for example, an alkyl group, such as a methyl group or an ethyl group. The alkyl group may be substituted with halogen such as fluorine. In the case of having a substituent group, the substituent group is preferably, for example, a perfluoroalkyl group, such as a trifluoromethyl group or a pentafluoroethyl group. When R² has a hydrogen atom or a monovalent organic group having 1 to 6 carbon atoms, the solubility of the resin composition with respect to an alkaline developer liquid is excellent. Thus, the developability can be improved.

Examples of the oxetane compound having the structure expressed by the general formula (1) given above include oxetanyl silsesquioxane and OXT-191 (product name, manufactured by TOAGOSEI CO., LTD.).

It is more preferred that the oxetane compound having the structure expressed by the general formula (1) given above have the structure expressed by the general formula (2) given below.

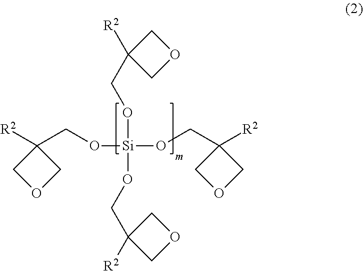

In the general formula (2) given above, R² is the same as R² given in the general formula (1). “m” is a repetition number and represents an integer of 1 or more.

In the general formula (2), with the silicate structure in which four oxygen atoms are bonded to silicon, the resin composition can be improved in thermal resistance. Further, many siloxane bonds are given, and hence the resin composition can be increased in the contrast between the exposed portion and the unexposed portion owing to the hydrolysis with an alkaline developer liquid.

Examples of the oxetane compound having the structure expressed by the general formula (2) given above include OXT-191 (product name, manufactured by TOAGOSEI CO., LTD.).

It is preferred that the content of the (B-1) oxetane compound in the resin composition according to this embodiment be 30 parts by mass or more, preferably 50 parts by mass or more with respect to the content of the (A) resin being 100 parts by mass. Further, it is preferred that the content of the (B-1) oxetane compound be 160 parts by mass or less, preferably 130 parts by mass or less with respect to the content of the (A) resin being 100 parts by mass. When the content of the (B-1) oxetane compound is 30 parts by mass or more, the resin composition is further improved in curability. Thus, a pattern having a higher aspect ratio can be formed. Meanwhile, when the content of the (B-1) oxetane compound is 160 parts by mass or less, the resin composition can be improved in the resolution given at the time of patterning.

### <(C) Epoxy Compound>

It is preferred that the resin composition according to this embodiment further contain an (C) epoxy compound. Examples of the (C) epoxy compound include an aromatic epoxy compound, an alicyclic epoxy compound, and an aliphatic epoxy compound. The resin composition may contain two or more kinds of the (C) epoxy compounds.

Examples of the aromatic epoxy compound include glycidyl ether of monovalent or polyvalent phenol having at least one aromatic ring (phenol, bisphenol A, phenol novolac, or a compound being an alkylene oxide adduct thereof).

Examples of the alicyclic epoxy compound include a compound obtained by epoxidizing, with an oxidant, a compound having at least one cyclohexane or cyclopentane ring (such as 3,4-epoxycyclohexylmethyl-3,4-epoxycyclohexanecarboxylate).

Examples of the aliphatic epoxy compound include polyglycidyl ether of aliphatic polyvalent alcohol or an alkylene oxide adduct thereof (such as 1,4-butanediol diglycidyl ether and 1,6-hexanediol diglycidyl ether), polyglycidyl ester of aliphatic polybasic acid (such as diglycidyl tetrahydrophthalate), an epoxidized product of a long-chain unsaturated compound (such as epoxidized soybean oil and epoxidized polybutadiene).

It is preferred that at least any one of the (B) oxetane compound or the (C) epoxy compound have a polyalkylene glycol chain. With a polyalkyelene glycol chain having high flexibility, the resin composition can suppress generation of cracks in a film or a cured product after drying.

It is preferred that a number-average molecular weight of a compound having a polyalkylene glycol chain be from 300 to 4,000 in view of the solubility with the (A) resin. When the number-average molecular weight is 300 or more, the resin composition can be improved in the solubility between the (A) resin and a compound having a polyalkylene glycol chain and in the flexibility. Thus, generation of cracks can be further suppressed. Meanwhile, when the number-average molecular weight is 4,000 or less, the resin composition can be adequately suppressed in the epoxy/oxetane equivalent and can be further improved in curability. Thus, a pattern having a higher aspect ratio can be formed. The chemical structure of a compound having a polyalkylene glycol chain can be analyzed by a combination of techniques such as nuclear magnetic resonance (NMR) spectroscopy, Fourier-transform infrared (FT-IR) spectroscopy, and high-performance liquid chromatography/mass spectrometry (HPLC/MS). The number-average molecular weight of a compound having a polyalkylene glycol chain can be measured by gel permeation chromatography (GPC).

It is preferred that the number of carbon atoms of an alkyelene group in a repetition unit of the polyalkylene glycol chain be, in view of hydrophilicity, from 2 to 6, more preferably 2. When the number of carbon atoms of the alkylene group falls within such range, the resin composition is excellent in the solubility with respect to an alkaline developer liquid and can be improved in developability.

Further, it is preferred that the number of epoxy groups or oxetanyl groups in at least any one of the (B) oxetane compound or the (C) epoxy compound having a polyalkylene glycol chain be 2 or more. Accordingly, the resin composition is further improved in curability. Thus, a pattern having a higher aspect ratio can be formed. Examples of such (B) oxetane compound include bis-[(3-ethyloxetane-3-yl)methoxy]polyethylene glycol, and examples of the (C) epoxy compound include polyethylene glycol diglycidyl ether and polypropylene glycol diglycidyl ether.

It is preferred that the (B) oxetane compound and the (C) epoxy compound each be a water-soluble compound in view of the solubility with respect to a water-based developer liquid at the time of development. Specifically, it is preferred that at least one kind of the (B) oxetane compound or the (C) epoxy compound be a water-soluble compound that dissolves in water of 900 parts by mass with respect to a compound of 100 parts by mass at 20° C. within 1 minute. Specifically, examples of the at least one kind of the (B) oxetane compound or the (C) epoxy compound include 3-methyl-3-hydroxymethyloxetane, 3-ethyl-3-hydroxymethyloxetane, glycerol polyglycidyl ether, polyglycerol polyglycidyl ether, ethylene glycol diglycidyl ether, polyethylene glycol diglycidyl ether, polypropylene glycol diglycidyl ether, phenol (EO)₅ glycidyl ether, and lauryl alcohol (EO)₁₅ glycidyl ether.

It is preferred that a total content of the (B) oxetane compound and the (C) epoxy compound in the resin composition according to this embodiment be 50 parts by mass or more, more preferably 70 parts by mass or more with respect to the content of the (A) resin being 100 parts by mass. Further, it is preferred that the total content of the (B) oxetane compound and the (C) epoxy compound be 170 parts by mass or less, more preferably 140 parts by mass or less with respect to the content of the (A) resin being 100 parts by mass. When the total content of those compounds is 50 parts by mass or more, the resin composition can suppress generation of cracks in a coating film. Meanwhile, when the total content of those compounds is 170 parts by mass or less, the resin composition can suppress expression of the tackiness of the coating film.

### <Photocationic Polymerization Initiator>

The photocationic polymerization initiator generates an acid due to light and causes cationic polymerization. Examples of the photocationic polymerization initiator include an aromatic iodonium salt, an aromatic sulfonium salt, and an aromatic borate salt. The resin composition may contain two or more kinds of the photocationic polymerization initiators. Among those, the photocationic polymerization initiator is preferably an aromatic sulfonium salt, and examples thereof include diphenyl[(phenylsulfanyl)phenyl]sulfonium=hexafluorophosphate, diphenyl[4-(phenylthio)phenyl]sulfonium-hexafluoroantimonate(V), diphenyl[4-(phenylsulfanyl)phenyl]sulfonium=trifluorotris(pentafluoroethane-1-ide)phosphate, and diphenyl[(phenylsulfanyl)phenyl]sulfonium=tetrakis(pentafluorophenyl)borate, as well as CPI-310B, CPI-310FG, CPI-410S, and CPI-410B (product names, all manufactured by San-Apro Ltd.).

The content of the photocationic polymerization initiator in the resin composition according to this embodiment is preferably 0.3 parts by mass or more with respect to the content of the (A) resin being 100 parts by mass. Accordingly, the resin composition is improved in curability. Thus, a pattern having a higher aspect ratio can be formed. Meanwhile, the content of the photocationic polymerization initiator is preferably 10 parts by mass or less with respect to the content of the (A) resin being 100 parts by mass. Accordingly, the resin composition can be improved in stability.

### <Other Components>

The resin composition according to this embodiment may contain, in addition to the (B) epoxy compound and the (C) oxetane compound, a cationically polimerizable compound other than those compounds. Examples of the cationically polimerizable compound other than the (B) epoxy compound and the (C) oxetane compound include an ethylenically unsaturated compound, bicyclic orthoester, spiro orthocarbonate, and spiro orthoester. The resin composition may contain two or more kinds of the cationically polimerizable compounds other than the (B) epoxy compound and the (C) oxetane compound.

Examples of the ethylenically unsaturated compound include aliphatic monovinyl ether, aromatic monovinyl ether, polyfunctional vinyl ether, styrene, and cationically polimerizable nitrogen-containing monomer. Examples of the aliphatic monovinyl ether include methylvinyl ether, ethylvinyl ether, butylvinyl ether, and cylcohexylvinyl ether. Examples of the aromatic monovinyl ether include 2-phenoxyethylvinyl ether, phenylvinyl ether, and p-methoxyphenylvinyl ether. Examples of the polyfunctional vinyl ether include butanediol-1,4-divinyl ether, and triethylene glycol divinyl ether. Examples of the styrenes include styrene, α-methyl styrene, and p-methoxystyrene-tert-butoxy styrene. Examples of the cationically polymerizable nitrogen-containing monomer include N-vinyl carbazole and N-vinyl pyrrolidone.

Examples of the bicyclic orthoester include 1-phenyl-4-ethyl-2,6,7-trioxabicyclo[2.2.2]octane and 1-ethyl-4-hydroxymethyl-2,6,7-trioxabicyclo-[2.2.2]octane.

Examples of the spiro orthocarbonate include 1,5,7,11-tetraoxaspiro[5.5]undecane and 3,9-dibenzyl-1,5,7,11-tetraoxaspiro[5.5]undecane.

Examples of the spiro orthoester include 1,4,6-trioxaspiro[4.4]nonane, 2-methyl-1,4,6-trioxaspiro[4.4]nonane, and 1,4,6-trioxaspiro[4.5]decane.

The resin composition according to this embodiment may further contain additives such as a sensitizer and a surfactant, inorganic particles, and a solvent. The solvent is preferably the one that dissolves components forming the resin composition, and examples thereof include: ethers such as ethylene glycol monoethyl ether, propylene glycol monomethyl ether, propylene glycol monoethyl ether, ethylene glycol dimethyl ether, ethylene glycol diethyl ether, and ethylene glycol dibutyl ether; alcohols such as ethylene glycol monoethyl ether acetate, propylene glycol monomethyl ether acetate, propyl acetate, butyl acetate, isobutyl acetate, 3-methoxybutyl acetate, 3-methyl-3-methoxybutyl acetate, 3-methyl-2-butanol, 3-methyl-3-methoxy butanol, and diacetone alcohol; and others such as N,N-dimethylformamide, N,N-dimethylacetoamide, dimethyl sulfoxide, and γ-butyloractone. The resin composition may contain two or more kinds of the solvents.

Examples of a manufacturing method for the resin composition according to this embodiment include a method of adding the items (A) and (B) as well as the (C) epoxy compound, the solvent, and other additives as needed and agitating them.

The resin composition according to this embodiment can be formed into various shapes such as varnish-like or film-like shapes for use.

### <Cured Product>

Next, a cured product according to one embodiment of the present invention is described. The cured product according to this embodiment is a cured product obtained by curing the resin composition mentioned above. The cured product according to this embodiment can be suitably used in, for example, a surface protection film for a semiconductor device or an interlayer insulation film, microelectromechanical systems (MEMS), and a barrier rib of a scintillator panel.

A manufacturing method for the cured product according to this embodiment is, for example, a method of irradiating (exposing) a resin composition coating film with actinic rays, developing and forming a pattern as needed, and thereafter curing the same by heating. As a result of the curing by heating, a thermal crosslinking reaction and, in the case of containing a photocationic polymerization initiator, a cationic polymerization reaction proceed so that the resin composition is cured. Examples of the actinic rays used for the exposure include ultraviolet rays, visible rays, electronic rays, and X-rays. The heating temperature is preferably from 120° C. to 300° C.

### <Scintillator Panel>

A scintillator panel according to one embodiment of the present invention includes a substrate, barrier ribs formed on the substrate, and a phosphor layer formed in cells defined by the barrier ribs. The barrier ribs are made of the cured product according to the embodiment described above. Through use of the resin composition according to the embodiment described above, barrier ribs having a high aspect ratio can easily be formed on the scintillator panel. Further, with such barrier ribs being provided, the brightness of the scintillator panel can be improved. Further, since the surface smoothness of the barrier ribs is excellent, the scintillator panel is improved in the efficiency of extracting the light emitted from the phosphor. Thus, the brightness can be improved.

Now, a mode of implementation of the scintillator panel according to this embodiment is described with reference to the drawings. It should be noted that the drawings are schematic. Further, this embodiment is not limited by the mode of implementation described below.

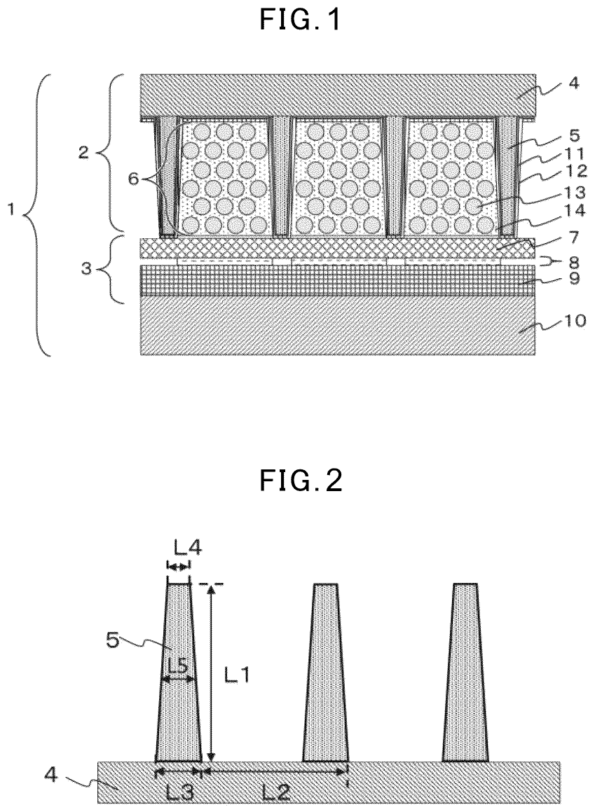

FIG. 1 shows a sectional view schematically illustrating a radiation detector member including the scintillator panel according to this embodiment. The radiation detector member 1 includes a scintillator panel 2 and an output substrate 3. The scintillator panel 2 includes a substrate 4, barrier ribs 5, and a phosphor layer 6 formed in cells defined by the barrier ribs 5. A metal reflective layer 11 is formed on a surface of the barrier rib 5, and an organic protective layer 12 is provided on a surface of the metal reflective layer 11. The phosphor layer 6 includes a phosphor 13 and a binder resin 14. The output substrate 3 includes, on a substrate 10 thereof, an output layer 9 and a photoelectric conversion layer 8 having a photodiode, which are arranged in the stated order. A diaphragm layer 7 may be provided on the photoelectric conversion layer 8. It is preferred that a light exit surface of the scintillator panel 2 and the photoelectric conversion layer 8 of the output substrate 3 be bonded to each other or in close contact with each other through intermediation of the diaphragm layer 7. Light emitted from the phosphor layer 6 reaches the photoelectric conversion layer 8, is subjected to photoelectric conversion, and is output. Now, each of the components is described.

### <Substrate>

It is preferred that a material forming the substrate be a material having radioparency. Examples of the material forming the substrate include the one exemplified as a material forming a substrate in WO 2021/200327 A1. Among those, it is preferred that the material forming the substrate be a high polymer material having high radioparency and high surface smoothness. Examples of a preferred high polymer material include polyesters such as polyethylene terephthalate and polyethylene naphthalate, polyamide, and polyimide.

In the case of a substrate made of a high polymer material, the thickness of the substrate is preferably 3.0 mm or less.

### <Barrier Ribs>

The barrier ribs are provided at least to form defined spaces (cells). Thus, in the scintillator panel, the size and pitch of pixels of the photoelectric conversion elements arranged in a grid pattern and the size and pitch of the cells of the scintillator panel are set so as to match, thereby being capable of allowing the pixels of the photoelectric conversion elements and the cells of the scintillator panel to correspond. In this manner, an image with high sharpness can be obtained.

It is preferred that the barrier ribs be made of the cured product according to this embodiment. When the barrier ribs made of the cured product of the resin composition according to this embodiment are provided, the scintillator panel can be improved in brightness. It is considered that the principle thereof is mainly in the following point. When the resin composition of the embodiment described above is used, the barrier ribs having a high aspect ratio can easily be formed on the scintillator panel. Accordingly, the scintillator panel may be increased in the filling amount of the phosphor in the phosphor layer. Thus, the brightness can be improved.

FIG. 2 is an enlarged sectional view schematically illustrating the substrate and the barrier rib part of the radiation detector member illustrated in FIG. 1. The barrier ribs 5 on the substrate 4 have a trapezoidal sectional shape with a height L1, a bottom width L3, and a top width L4 and are arranged at an interval L2. A width of the barrier rib at a position in the half of the height L1 is referred to as a middle width L5.

It is preferred that the height L1 of the barrier rib be 100 μm or more, more preferably 200 μm or more. When the height L1 is 100 μm or more, the scintillator panel can be increased in the phosphor filling amount. Thus, the brightness can be further improved. Meanwhile, it is preferred that the height L1 of the barrier rib be 3,000 μm or less, more preferably 1,000 μm or less. When the height L1 is 3,000 μm or less, the scintillator panel can suppress absorption of light emitted from the phosphor itself. Thus, the brightness can be further improved.

It is preferred that the interval L2 between adjacent barrier ribs be 40 μm or more, more preferably 1,000 μm or less. It is preferred that the bottom width L3 of the barrier rib be 3 μm or more, more preferably 150 μm or less. It is preferred that the top width L4 of the barrier rib 5 be 3 μm or more and 30 μm or less.

It is preferred that an aspect ratio (L1/L5) of the height L1 of the barrier rib to the middle width L5 of the barrier rib be 5.0 or more. Accordingly, the scintillator panel can be increased in the filling amount of the phosphor. Thus, the brightness can be further improved. It is preferred that the aspect ratio (L1/L5) be 12 or more, more preferably 14 or more, still more preferably 15 or more. Meanwhile, it is preferred that the aspect ratio (L1/L5) be 100 or less, more preferably 50 or less. Accordingly, the scintillator panel can be improved in the strength of the barrier rib.

The height L1 of the barrier rib, the interval L2 of adjacent barrier ribs, the bottom width L3, the top width L4, and the middle width L5 can be measured by cleaving a cross section perpendicular to the substrate or by observing a cross section that has been exposed using a polishing device such as a cross-section polisher with a scanning electronic microscope. Here, a width of the barrier rib at a contact portion between the barrier rib and the substrate is represented by L3. Further, a width of the barrier rib at the topmost part is represented by L4, and a width of the middle part at the position corresponding to the half of the height L1 is represented by L5. Each of the lengths L1 to L5 is calculated by averaging measurement values of the barrier rib at three positions that are randomly selected.

A method of setting the aspect ratio (L1/L5) within the above-mentioned range is preferably a method of forming barrier ribs made of the resin composition according to this embodiment, and it is preferred that components forming the resin composition and the content fall within the above-mentioned preferred range.

### <Metal Reflective Layer>

In the scintillator panel according to this embodiment, it is preferred that the barrier rib have a reflective layer containing metal on a surface thereof (hereinafter referred to as “metal reflective layer”). The metal reflective layer is only required to be provided at least at a part of the barrier rib. The metal reflective layer has a high reflectance even when it is a thin film. Thus, when the metal reflective layer being a thin film is provided, the filling amount of the phosphor is less liable to be reduced, and hence the scintillator panel is further improved in brightness. Examples of the metal reflective layer include the one exemplified as a metal reflective layer in WO 2019/181444 A1.

### <Protective Layer>

It is preferred that the scintillator panel according to this embodiment have a protective layer on a surface of the metal reflective layer. When the protective layer is provided on the metal reflective layer, the metal reflective layer can be reduced in color change even in a case in which an alloy that is poor in the resistance to color change in an atmosphere is used. Accordingly, in the scintillator panel, reduction in the reflectance of the metal reflective layer caused by a reaction between the metal reflective layer and the phosphor layer is suppressed. Thus, the brightness can be further improved.

Either an inorganic protective layer or an organic protective layer may be suitably used as the protective layer. The protective layer may also be used as a stack of the inorganic protective layer and the organic protective layer.

### <Inorganic Protective Layer>

The inorganic protective layer has a low permeability for water vapor, and thus is suitable as a protective layer. Examples of the inorganic protective layer include the one exemplified as an inorganic protective layer in WO 2019/181444 A1.

### <Organic Protective Layer>

It is preferred that the organic protective layer be formed of a high polymer compound that is excellent in chemical resistance and contain polysiloxane or amorphous fluoropolymer as a main component. Examples of the organic protective layer include the one exemplified as an organic protective layer in WO 2019/181444 A1. Examples of the polysiloxane and the amorphous fluoropolymer include the ones exemplified as a material forming the organic protective layer in WO 2021/200327 A1.

### <Phosphor Layer>

The scintillator panel according to this embodiment has the phosphor layer in the cells defined by the barrier ribs.

The phosphor layer absorbs energy of a radiation such as input X-rays and emits an electromagnetic wave having a wave length within the range of from 300 nm to 800 nm, that is, the light falling within the range of from ultraviolet light to infrared light with visible light as a center. The light emitted from the phosphor layer is subjected to photoelectric conversion in the photoelectric conversion layer and then output as an electric signal through the output layer. It is preferred that the phosphor layer have a phosphor and a binder resin.

### <Phosphor>

Examples of the phosphor include the one exemplified as a phosphor in WO 2021/200327 A1. As the light emission efficiency is high, the phosphor is preferably a terbium-activated rare-earth oxysulfide phosphor.

### <Binder Resin>

Examples of the binder resin include the one exemplified a binder resin in WO 2021/200327 A1.

It is preferred that the binder resin be in contact with the protective layer. In this case, it is only required that the binder resin be in contact with at least a part of the protective layer. As a result, in the scintillator panel, the phosphor is less liable to drop off the cells. The binder resin may fill the cells substantially without a gap as illustrated in FIG. 1 or may fill the cells with a gap.

As described above, with the scintillator panel according to this embodiment, an image with high brightness can be obtained.

### <Manufacturing Method for Scintillator Panel>

It is preferred that a manufacturing method for a scintillator panel according to one embodiment of the present invention include, for example, a barrier rib forming step of forming barrier ribs on a substrate to define cells, a reflective layer forming step of forming a metal reflective layer on a surface of the barrier ribs as needed, and a filling step of filling the cells defined by the barrier ribs with a phosphor. The barrier rib contains the cured product according to the embodiment described above. In the following, each of the steps is described. In the following description, description of the items that are in common with the items described in the embodiment of the scintillator described above are suitably omitted.

### <Barrier Rib Forming Step>

The barrier rib forming step using the resin composition according to this embodiment is described. The resin composition according to the embodiment described above is applied entirely or partially on the surface of the substrate to obtain a coating film. Examples of a method of applying the resin composition include a screen-printing method and a method using a coater such as a bar coater, a roll coater, a die coater, or a blade coater. The thickness of the coating film can be adjusted in accordance with the number of times of application, the mesh size of the screen, the viscosity of the resin composition, and the like.

Next, a pattern is formed from the resin composition coating film formed by the method described above. When the resin composition has photosensitivity, the resin composition coating film is irradiated with and exposed to actinic rays through a mask having a desired pattern. Examples of the actinic rays used for the exposure include ultraviolet rays, visible rays, electronic rays, and X-rays. In this embodiment, for the actinic rays, it is preferred that i-line (365 nm), h-line (405 nm), and g-line (436 nm) of a mercury lamp be used.

After the exposure, the exposed portion is removed using a developer liquid. Examples of the developer liquid include the one exemplified as a developer liquid in WO 2021/200327 A1.

Development can be performed by methods such as spraying the developer liquid described above onto a coated surface, applying the developer liquid as a puddle onto the coating film surface, immersing the coating film surface in the developer liquid, or immersing the coating film surface with application of an ultrasonic wave. Development conditions such as the development time and the temperature of the developing step developer liquid may be any conditions as long as the exposed portion is removed and the pattern can be formed.

It is preferred that, after the development, rinsing with water be performed. The rinsing may be performed using water with alcohols such as ethanol and isopropyl alcohol or esters such as lactic ethyl and propylene glycol monomethyl ether acetate added thereto.

Further, baking may be performed before the development as needed. Accordingly, the resolution of the pattern after the development may be improved so that the allowable range of the development conditions is increased. It is preferred that the baking temperature fall within the range of from 50° C. to 180° C., more preferably the range of from 60° C. to 120° C. It is preferred that the time be seconds to several hours.

After formation of the pattern, in the coating film of the photosensitive resin composition, an unreacted cationically polimerizable compound or a cationic polymerization initiator remains. Thus, those components may be thermally decomposed and generate gas at the time of a thermal crosslinking reaction described later. In order to avoid such a situation, it is preferred that the entire surface of the resin composition coating film after the formation of the pattern be irradiated with the above-mentioned exposure light so that an acid be generated in advance from the cationic polymerization initiator. In such a manner, at the time of the thermal crosslinking reaction, the reaction of the unreacted cationically polimerizable compound progresses. Thus, generation of the gas derived from the thermal decomposition can be suppressed.

After the development, with the temperature of from 120° C. to 300° C. added to allow the thermal crosslinking reaction to progress, the resin composition is cured so that the barrier ribs can be obtained. The crosslinking can improve the thermal resistance and the chemical resistance. The method of such heating may be selected from a method of selecting a certain temperature and gradually raising the temperature or a method of selecting a certain temperature range and performing the process for 5 minutes to 5 hours while continuously increasing the temperature.

In the manufacturing method for a scintillator panel according to this embodiment, the base material given at the time of forming the barrier ribs may be used as the substrate of the scintillator panel. After removal of the barrier ribs from the base material, the removed barrier ribs may be placed on the substrate for use. As a method of removing the barrier ribs from the base material, any known technique may be used, such as a technique of providing a removal assistance layer between the base material and the barrier ribs.

When the barrier rib has the metal reflective layer, the inorganic protective layer, and/or the organic protective layer on a surface thereof, examples of a method of forming those layers include a method exemplified in WO 2019/181444 A1 or WO 2021/200327 A1 as a process for forming those layers.

### <Semiconductor Device>

The cured product according to one embodiment of the present invention may be suitably used for a semiconductor device, in particular, an inductor having an insulation film and a coil, and the cured product according to this embodiment is used as the insulation film. A pattern having a high aspect ratio can be easily formed with the resin composition according to the embodiment described above. Thus, it is preferred that the resin composition according to the embodiment described above be used for an inductor being a semiconductor device having a cured product with a high aspect ratio.

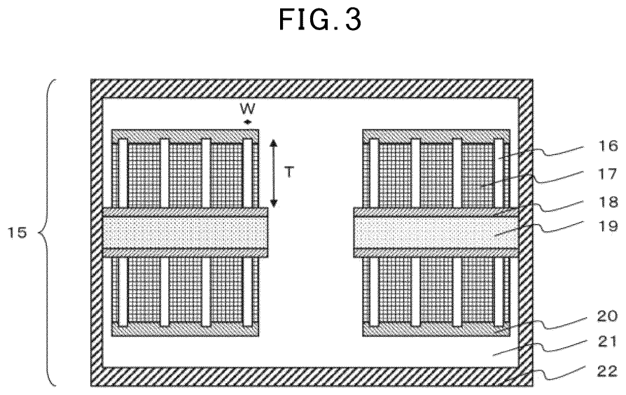

FIG. 3 shows a sectional view schematically illustrating a configuration of an inductor according to this embodiment. An inductor 15 has, through intermediation of resin layers 18 respectively provided on an upper side and a lower side of a substrate 19, coils 17 and insulation films 16 maintaining insulation between the coils 17 provided on each of the upper side and the lower side. Further, the inductor 15 has a magnetic agent 21 through intermediation of the insulation film 20 and is sealed with a mold resin 22.

It is preferred that the cured product according to the embodiment described above be used for the insulation films 16. When the cured product according to the embodiment described above is used for the insulation films 16, the inductor 15 may exhibit sufficient insulation even in the case in which the insulation film 16 has a small pattern width W. Accordingly, the inductor 15 can have a large sectional area of wiring of the coils 17. Thus, the inductance can be increased.

In view of increasing the sectional area of the coil 17, it is preferred that the insulation film 16 have a film thickness T of 40 μm or more, more preferably 80 μm or more. Meanwhile, in view of reducing a film stress, it is preferred that the insulation film 16 have a film thickness T of 300 μm or less, more preferably 200 μm or less.

In view of increasing the wiring density of the coil 17, it is preferred that an aspect ratio obtained by dividing a film thickness of the insulation film 16 by a pattern width be 4 or more, more preferably 8 or more. Meanwhile, in view of maintaining the insulation, it is preferred that the insulation film 16 have an aspect ratio of 30 or less, more preferably 20 or less.

In the above, one embodiment of the present invention has been described. The present invention is not particularly limited to the embodiment described above. The embodiment described above mainly describes the invention having the following configuration.

(1) A resin composition, comprising: a (A) resin; an (B) oxetane compound; and a photocationic polymerization initiator, wherein the (A) resin includes a resin having an alkali-soluble group, and wherein the (B) oxetane compound includes a (B-1) compound having four or more oxetanyl groups.

(2) The resin composition according to item (1), wherein the (B-1) compound having four or more oxetanyl groups has a structure expressed by the following general formula (1).

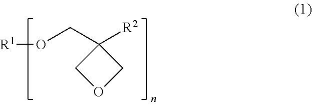

(In the general formula (1), R¹ represents an n-valent group having a siloxane bond. R² represents a hydrogen atom or a monovalent organic group having 1 to 6 carbon atoms. “n” represents a range of from 4 to 30.)

(3) The resin composition according to item (1) or (2), further comprising an (C) epoxy compound.

(4) The resin compound according to any one of items (1) to (3), wherein at least any one of the (B) oxetane compound or the (C) epoxy compound has a polyalkylene glycol chain.

(5) The resin composition according to item (4), wherein the polyalkylene glycol chain has a weight-average molecular weight of from 300 to 4,000.

(6) The resin composition according to any one of items (1) to (5), wherein a content of the (B-1) compound having four or more oxetanyl groups is from 30 parts by mass to 160 parts by mass with respect to 100 parts by mass of the (A) resin.

(7) A cured product obtained by curing the resin composition of any one of items (1) to (6).

(8) A scintillator panel, comprising: a substrate; barrier ribs formed on the substrate; and a phosphor layer formed in cells defined by the barrier ribs, wherein the barrier ribs are made of the cured product of item (7).

(9) The scintillator panel according to item (8), wherein the barrier ribs have a height L1 of 100 μm or more.

(10) The scintillator panel according to item (8) or (9), wherein an aspect ratio (L1/L5) of the height L1 of the barrier ribs with respect to a middle width L5 of the barrier ribs is 5.0 or more.

(11) An inductor comprising an insulation film and a coil, wherein the insulation film is the cured product of item (7).

### Example

Now, the present invention is described in more detail with reference to Examples and Comparative examples. Compounds used in Examples and Comparative examples were synthesized by the following methods.

### Synthesis of Polyimide A-1

Under a dry nitrogen gas stream, 29.30 g (0.08 mol) of 2,2-bis(3-amino-4-hydroxyphenyl)hexafluoropropane (hereinafter simply referred to as “BAHF”) (manufactured by Tokyo Chemical Industry Co., Ltd.) was added to 80 g of γ-butyrolactone (hereinafter simply referred to as “GBL”) (manufactured by FUJIFILM Wako Pure Chemical Corporation), and dissolved by stirring at 120° C. Next, 30.03 g (0.1 mol) of an acid anhydride “RIKACID®” TDA-100 (hereinafter simply referred to as “TDA-100”) (manufactured by New Japan Chemical Co., Ltd.) was added together with 20 g of GBL, and the mixture was stirred at 120° C. for 1 hour and then at 200° C. for 4 hours to obtain a reaction solution. Next, the reaction solution was poured into 3 L of water to cause deposition of a white precipitate. The precipitate was collected by filtration, washed with water three times, and then dried in a vacuum dryer at 80 C° for 5 hours to obtain polyimide A-1 having a weight-average molecular weight of 4,000 and a basic functional group equivalent of 1,000 g/eq or more.

### Synthesis of Polyimide A-2

Under a dry nitrogen gas stream, 32.96 g (0.09 mol) of BAHF was added to 80 g of GBL and dissolved by stirring at 120° C. Next, 30.03 g (0.1 mol) of TDA-100 was added together with 20 g of GBL, and the mixture was stirred at 120° C. for 1 hour and then at 200° C. for 4 hours to obtain a reaction solution. Next, the reaction solution was poured into 3 L of water to cause deposition of a white precipitate. The precipitate was collected by filtration, washed with water three times, and then dried in a vacuum dryer at 80 C.° for 5 hours to obtain polyimide A-2 having a weight-average molecular weight of 8,000 and a basic functional group equivalent of 1,000 g/eq or more.

### Synthesis of Polyamideimide A-3

BAHF (18.3 g, 0.05 mol) (manufactured by Tokyo Chemical Industry Co., Ltd.) was dissolved in 100 mL of acetone (manufactured by Tokyo Chemical Industry Co., Ltd.) and propylene oxide (17.4 g, 0.3 mol) (manufactured by FUJIFILM Wako Pure Chemical Corporation), and the solution was cooled to −15° C. Then, a solution obtained by dissolving 3-nitrobenzoylchloride (20.4 g, 0.11 mol) (manufactured by Tokyo Chemical Industry Co., Ltd.) in 100 mL of acetone (manufactured by Tokyo Chemical Industry Co., Ltd.) was added dropwise. After completion of the dropwise addition, the resultant was stirred at −15° C. for 4 hours. After that, the temperature was recovered to room temperature. A deposited white solid was collected by filtration and vacuum-dried at 50° C.

30 g of the obtained white solid was placed in a stainless steel autoclave of 300 mL, dispersed in 250 mL of methyl cellosolve (manufactured by Tokyo Chemical Industry Co., Ltd.), and 2 g of 5 mass % palladium-carbon was added. Hydrogen was introduced thereto with a balloon, and the resultant was stirred at room temperature for a reduction reaction. After about 2 hours, it was confirmed that the balloon was not deflated any more, and the stirring was stopped. After completion of the stirring, the palladium compound as a catalyst was removed by filtration, and the filtrate was condensed with a rotary evaporator to obtain a hydroxyl group-containing diamine compound (a).

Under a dry nitrogen gas stream, 31.4 g (0.08 mol) of the hydroxyl group-containing diamine compound (a) was added to 80 g of GBL (manufactured by FUJIFILM Wako Pure Chemical Corporation), and the mixture was stirred at 120° C. Next, 30.0 g (0.1 mol) of TDA-100 (manufactured by New Japan Chemical Co., Ltd.) was added together with 20 g of GBL, and the mixture was stirred at 120° C. for 1 hour and then at 200° C. for 4 hours to obtain a reaction solution. Next, the reaction solution was poured into 3 L of water to cause deposition of a white precipitate. The precipitate was collected by filtration, washed with water three times, and then dried in a vacuum dryer at 80° C. for 5 hours to obtain polyamideimide A-3 having a weight-average molecular weight of 5,000 and a basic functional group equivalent of 1,000 g/eq or more.

### Synthesis Example 4: Synthesis of Oxetane Compound B-1a

90.0 g (0.01 mol) of a novolac resin (number-average molecular weight of 900) (manufactured by Meiwa Plastic Industries, Ltd.) was dissolved in 100 mL of dimethyl sulfoxide (manufactured by FUJIFILM Wako Pure Chemical Corporation), purged with nitrogen gas, added with 60.0 g of 49 mass % aqueous potassium hydroxide (manufactured by FUJIFILM Wako Pure Chemical Corporation), and stirred at 90° C. for 1 hour. Next, 60.5 g (0.5 mol) of 3-(chloromethyl)-3-methyloxetane (manufactured by Tokyo Chemical Industry Co., Ltd.) was slowly added dropwise using a dropping funnel while stirring. After that, the mixture was stirred at 90° C. for 5 hours to cause a reaction, and then the reaction solution was poured into 1 L of water to cause deposition of a white precipitate. The precipitate was collected by filtration, washed with water three times, and then dried in a vacuum dryer at 80° C. for 5 hours to obtain an oxetane compound B-1 having 9 oxetanyl groups per molecule on average (a water-insoluble compound not satisfying the general formula (1) and not having a polyalkylene glycol chain).

### Synthesis of Epoxy Compound C-5

20.0 g (0.005 mol) of polyethylene glycol (number-average molecular weight of 4,000) (manufactured by Tokyo Chemical Industry Co., Ltd.) and 13.4 g (0.15 mol) of epichlorohydrin (manufactured by Tokyo Chemical Industry Co., Ltd.) were dissolved in 200 mL of toluene (manufactured by FUJIFILM Wako Pure Chemical Corporation), and then 6.0 g (0.15 mol) of sodium hydroxide (manufactured by FUJIFILM Wako Pure Chemical Corporation) was added thereto, followed by stirring at 50 C.° for 7 hours to cause a reaction. After cooling to room temperature, the reaction liquid was washed three times with distilled water and once with saturated brine, and an organic layer was extracted. The solvent was distilled off using an evaporator, and the residue was dried in a vacuum dryer at 80° C. for 5 hours to obtain a bifunctional epoxy compound (C-5) having a polyethylene glycol chain (number-average molecular weight of 4,200).

Other raw materials used in Examples and Comparative examples are shown below.

### (A) Resin

A-4: “Maruka Linker®” M (manufactured by Maruzen Petrochemical), polyparahydroxystyrene, a weight-average molecular weight of 4,000, a basic functional group equivalent of 1,000 g/eq or more, resin
A-5: a copolymer of methacrylic acid/methyl methacrylate/styrene=40/40/30 (mass ratio) with an addition reaction of 0.4 equivalents of glycidyl methacrylate to carboxyl groups, a weight-average molecular weight of 43,000, an acid number of 100 mgKOH/g

### (B) Oxetane Compound

B-1b: a water-insoluble compound obtained by fractionating low molecular weight components of OXT-191 (manufactured by TOAGOSEI CO., LTD.) by GPC, having 6 oxetanyl groups on average, expressed by the general formula (1), where R¹ represents polysilicate, R² represents an ethyl group, without a polyalkyelene glycol chain
B-1c: a water-insoluble compound of OXT-191 (manufactured by TOAGOSEI CO., LTD.), having 12 oxetanyl groups on average, expressed by the general formula (1), where R¹ represents polysilicate, R² represents an ethyl group, without a polyalkyelene glycol chain
B-1d: a water-insoluble compound obtained by fractionating polymer components of OXT-191 (manufactured by TOAGOSEI CO., LTD.) by GPC, having 18 oxetanyl groups on average, expressed by the general formula (1), where R¹ represents polysilicate, R² represents an ethyl group, without a polyalkyelene glycol chain,
B-2: a water-insoluble compound of OXIPA (manufactured by Ube Industries, Ltd.), without a polyalkylene glycol chain

### (C) Epoxy Compound

C-1: “TEPIC®”-VL (manufactured by Nissan Chemical Industries, Ltd.), a trifunctional epoxy compound, a water-insoluble compound without a polyalkylene glycol chain
C-2: “DENACOL®” EX-171 (manufactured by Nagase ChemteX Corporation), a monofunctional epoxy compound having a polyethylene glycol chain, a number-average molecular weight of 770, a water-soluble compound
C-3: “DENACOL®” EX-861 (manufactured by Nagase ChemteX Corporation), a bifunctional epoxy compound having a polyethylene glycol chain, a number-average molecular weight of 1,100, a water-soluble compound
C-4: “DENACOL®” EX-850 (manufactured by Nagase ChemteX Corporation), a bifunctional epoxy compound having a polyethylene glycol chain, a number-average molecular weight of 220, a water-soluble compound
C-6: “DENACOL®” EX-931 (manufactured by Nagase ChemteX Corporation), a bifunctional epoxy compound having a polypropylene glycol chain, a number-average molecular weight of 1,000, a water-insoluble compound

### (D) Photocationic Polymerization Initiator

CPI-410S (manufactured by San-Apro Ltd.), aromatic sulphonium salt

### (Others)

Photosensitive monomer M-1: trimethylolpropane triacrylate
Photosensitive monomer M-2: tetrapropylene glycol dimethacrylate
Photopolymerization initiator: 2-benzyl-2-dimethylamino-1-(4-morpholinophenyl)butanone-1 (manufactured by BASF SE)
Polymerization inhibitor: 1,6-hexanediol-bis[(3,5-di-t-butyl-4-hydroxyphenyl)propionate])
Ultraviolet absorber: 0.3 mass % solution of y-butyrolactone of Sudan IV (manufactured by TOKYO OHKA KOGYO CO., LTD.)
Viscosity modifier: Flow-non EC121 (manufactured by KYOEISHA CHEMICAL Co., LTD.)
Low-softening-point glass powder: 27 mass % of SiO₂, 31 mass % of B₂O₃, 6 mass % of ZnO, 7 mass % of Li₂O, 2 mass % of MgO, 2 mass % of CaO, 2 mass % of BaO, and 23 mass % of Al₂O₃, a refractive index (ng) of 1.56, a glass softening temperature of 588° C., a thermal expansion coefficient of 70×10⁻⁷(K⁻¹), an average particle size of 2.3 μm

For the water solubility of the oxetane compound (B) and the epoxy compound (C), 1.0 g of each compound was placed in 9.0 g of water and stirred at 20° C. for 1 minute, the presence or absence of insoluble matter was visually observed, and a compound in which insoluble matter was not observed was defined as a water-soluble compound.

Next, evaluation methods in Examples and Comparative examples will be described.

### <Tackiness>

In each of Examples and Comparative examples, a finger was pressed against a surface of a varnish coating film after drying prepared in the formation of the barrier rib, and evaluation was performed according to the following evaluation criteria.

### (Evaluation Criteria)

A: No stickiness was observed.
B: Slight stickiness was observed, but the resin composition did not adhere to the finger.
C: Stickiness was observed and the resin composition adhered to the finger.

### <Crack Resistance>

In each of Examples and Comparative examples, each of the varnish coating film after drying prepared in the formation of the barrier rib and the film after exposure and heating or after exposure was visually observed, and the crack resistance was evaluated according to the following criteria from a total value of the number of cracks generated for the observation area of 100 cm².

### (Evaluation Criteria)

4: No crack was observed.
3: The number of cracks generated was 1 or more and less than 25.
2: The number of cracks generated was 25 or more and less than 100.
1: The number of cracks generated was 100 or more.

### <Developability>

In each of Examples and Comparative examples, the developability was evaluated according to the following criteria from the time required for the unexposed portion to be completely dissolved during development.

### (Evaluation Criteria)

4: The time required for the unexposed area to be completely dissolved during development was less than 10 minutes.
3: The time required for the unexposed area to be completely dissolved during development was 10 minutes or more and less than 20 minutes.
2: The time required for the unexposed portion to be completely dissolved during development was 20 minutes or more and less than 30 minutes.
1: The time required for the unexposed area to be completely dissolved during development was 30 minutes or more.

### <Adhesion>

In each of Examples and Comparative examples, the interface between the barrier rib and the substrate was visually observed at the completion of development, and the adhesion was evaluated according to the following criteria.

### (Evaluation Criteria)

A: No peeling was observed.
B: Peeling was partially observed.
C: Peeling was observed in the entirety.

### <Resolution>

The cross section of the barrier ribs in the grid pattern formed in each of Examples and Comparative examples was exposed by cleaving, and the middle L5 widths of three barrier ribs randomly selected from the barrier ribs corresponding to the smallest openings in which no lumps or residues were observed in the pattern among the barrier ribs corresponding to the mask openings having line widths of 12 μm, 15 μm, and 20 μm in each of Examples and Comparative examples 1 and 2, and the barrier ribs formed in Comparative Example 3 were measured at a magnification of 200× using a scanning electron microscope S2400 (manufactured by Hitachi, Ltd.), and the mean values were calculated.

### <Aspect Ratio>

For the barrier ribs in the grid pattern formed in each of Examples and Comparative examples, the height L1 of each of the three barrier ribs at which the middle widths L5 were measured in the evaluation of the <Resolution>described above was measured through the observation with the same enlargement and the mean values were calculated, and the aspect ratios (L1/L5) were calculated from the mean values of the middle widths L5 calculated in the evaluation of the <Resolution>described above.

### <Relative Brightness>

At the center of a sensor face of an X-ray detector PaxScan 2520V (manufactured by Varex), the scintillation counter panel obtained in each of Examples and Comparative examples was arranged in alignment so that the cells correspond to the pixels of the sensor on the one-to-one basis, and the end of the substrate was fixed with an adhesive tape to prepare a radiation detector. The detector was irradiated with X-rays from an X-ray radiator L9181-02 (manufactured by Hamamatsu Photonics K.K.) under the conditions of a tube voltage of 50 kV and a distance of 30 cm between the X-ray tube and the detector to acquire an image. In the obtained image, an average value of digital values of 256×256 pixels at the center of the light emitting position of the scintillator panel was measured as the brightness, and a relative value given when the brightness of Comparative Example 2 was set to 100 was calculated as a relative brightness.

### Example 1

### <Preparation of Varnish>

10 g of the polyimide A-1 obtained in Synthesis example 1 as the (A) resin, 12 g of the oxetane B-1a obtained in Synthesis example 4 as the (B) oxetane compound, and 0.10 g of CPI-410S as the photocationic polymerization initiator were weighed and dissolved in GBL. The amount of GBL added was adjusted so that the solid content concentration was 60 mass %, with the components other than GBL as the solid content. After that, the mixture was filtered under pressure through a filter having a retention particle size of 1 μm to obtain a photosensitive polyimide varnish.

### <Formation of Barrier Rib>

As a substrate, a PET film having a length of 125 mm, a width of 125 mm, and a thickness of 0.25 mm was used. The photosensitive polyimide varnish was applied to the surface of the substrate using a die coater so that the thickness after thermal crosslinking and curing was 350 μm, and dried to obtain a coating film of the photosensitive polyimide varnish.

Next, a coating film of the photosensitive polyimide vanish was exposed through a chromium mask having openings in a grid pattern with a pitch of 200 μm and line widths of 12 μm, 15 μm, and 20 μm by using an ultra-high pressure mercury lamp at an exposure amount of 5000 mJ/cm². After the exposure, post-exposure heating was performed at 100° C. for 90 minutes using a hot-air oven. The coating film after the exposure and heating was developed in a 0.5 mass % potassium hydroxide aqueous solution at 30° C., and the unexposed portion was removed, thereby obtaining a grid pattern. The obtained grid pattern was heated in air at 200° C. for 60 minutes to cause thermal crosslinking and curing, thereby forming a grid-pattern barrier ribs.

### <Preparation of Scintillator Panel>

### <Formation of Metal Reflective Layer and Inorganic Protective Layer>

Sputtering was performed on the formed grid-pattern barrier ribs using a commercially available sputtering apparatus and using APC (manufactured by FURUYA METAL Co., Ltd.), which is a silver alloy containing palladium and copper, as a sputtering target to form a metal reflective layer. The sputtering was performed under the condition that a flat glass plate was disposed in the vicinity of the barrier rib substrate and the metallic thickness on the flat glass plate was the 300 nm. After the metal reflective layer was formed, SiN was formed as an inorganic protective layer in the same vacuum batch. At this time, the inorganic protective layer was formed under the condition that the thickness on the glass substrate was 100 nm.

### <Formation of Organic Protective Layer>

1 part by mass of an amorphous fluororesin “CYTOP©” CTL-809M was mixed with 1 part by mass of a fluorine-based solvent CT-SOLV180 (manufactured by AGC Inc.) to prepare a resin solution. The obtained resin solution was vacuum-printed on the barrier rib on which the metal reflective layer and the inorganic protective layer were formed, dried at 90° C. for 1 hour, and further heated at 190° C. for 1 hour to form an organic protective layer. The cross section of the barrier rib was exposed using a triple ion milling device EMTIC3X (manufactured by LEICA), and the thickness of the organic protective layer on the side surface at the central portion of the barrier rib in the height direction, which was measured by imaging using a field emission scanning electron microscope (FE-SEM) Merlin (manufactured by Zeiss), was 1 μm.

### <Phosphor>

A commercially available GOS:Tb (gadolinium oxysulfide doped with Tb) phosphor powder was used as it was. The average particle size D50 measured with a particle size analyzer MT3300 (manufactured by Nikkiso Co., Ltd.) was 11 μm.

### <Binder Resin of Phosphor Layer>

The raw materials used for preparing the binder resin of the phosphor layer are as follows.
Binder resin: ETHOCEL® 7cp (manufactured by Dow Chemical Company)
Solvent: benzyl alcohol (manufactured by FUJIFILM Wako Pure Chemical Corporation).

### <Formation of Phosphor Layer>

A phosphor paste was prepared by mixing 10 parts by mass of a phosphor GOS:Tb (gadolinium oxysulfide doped with Tb) with 5 parts by mass of the binder resin “ETHOCEL®” 7cp (manufactured by Dow Chemical Company) dissolved in the benzyl alcohol (manufactured by FUJIFILM Wako Pure Chemical Corporation) to a concentration of 10 mass %. The average particle size D50 of the phosphor measured using the particle size analyzer MT3300 (manufactured by Nikkiso Co., Ltd.) was 11 μm.

The obtained phosphor paste was vacuum-printed on the barrier rib on which the metal reflective layer, the inorganic protective layer, and the organic protective layer were formed so that the volume fraction of the phosphor became 65%, and dried at 150° C. for 15 minutes to form a phosphor layer, thereby obtaining a scintillator panel.

### Examples 2 to 19 and Comparative Examples 1 and 2

A barrier rib and a scintillator panel were produced in the same manner as in Example 1 except that the types and addition amounts (parts by mass) of the (A) resin, the (B) oxetane compound, and the (C) epoxy compound were changed as shown in Tables 1 and 2.

### Comparative Example 3

4 parts by mass of the photosensitive monomer M-1, 6 parts by mass of the photosensitive monomer M-2, 24 parts by mass of the photosensitive polymer, 6 parts by mass of the photopolymerization initiator, 0.2 parts by mass of the polymerization inhibitor, and 12.8 parts by mass of the ultraviolet absorber solution were dissolved in 38 parts by mass of GBL (manufactured by FUJIFILM Wako Pure Chemical Corporation) by heating at a temperature of 80° C. to obtain a photosensitive resin composition.

After 50 parts by mass of the low-softening-point glass powder was added to 50 parts by mass of the obtained photosensitive resin composition, the mixture was kneaded using a three-roller kneader to obtain a glass powder-containing paste.

### <Formation of Barrier Rib>

A soda-lime glass plate having a length of 125 mm, a width of 125 mm, and a thickness of 0.7 mm was used as a substrate. A glass powder-containing paste was applied to the surface of the substrate using a die coater so that the thickness given after thermal cross-linking and curing was 350 μm, and dried, thereby obtaining a coating film of a glass powder-containing paste.

Next, a coating film of the glass powder-containing paste was exposed through a chromium mask having grid-pattern openings with a pitch of 200 μm and a line width of 10 μm by using an ultra-high pressure mercury lamp at an exposure amount of 300 mJ/cm². The coating film after the exposure was developed in a 0.5 mass % ethanolamine aqueous solution at 30° C., and the unexposed portion was removed to obtain a grid-like pre-firing pattern. The obtained grid-like pre-firing pattern was fired in air at 580° C. for 15 minutes to form grid-pattern barrier ribs containing glass as a main component.

Using the obtained barrier rib substrate, a scintillator panel was produced in the same manner as in Example 1.

With regard to each of Examples and Comparative examples, the results evaluated by the method mentioned above are shown in Tables 1 and 2.

TABLE 1

| | | | Exam- | Exam- | Exam- | Exam- | Exam- | Exam- | Exam- | Exam- | Exam- | Exam- |
|---|---|---|---|---|---|---|---|---|---|---|---|---|
| | | | ple 1 | ple 2 | ple 3 | ple 4 | ple 5 | ple 6 | ple 7 | ple 8 | ple 9 | ple 10 |
| Composition | (A) Resin | (A-1) | 100 | 100 | 100 | 100 | 100 | 100 | 100 | 100 | 100 | 100 |
| (parts by mass) | | (A-2) | — | — | — | — | — | — | — | — | — | — |
| | | (A-3) | — | — | — | — | — | — | — | — | — | — |
| | | (A-4) | — | — | — | — | — | — | — | — | — | — |
| | (B) Oxetane | (B-1a) | 120 | — | — | — | — | — | — | — | — | — |
| | compound | (B-1b) | — | — | — | 100 | — | — | — | — | — | — |
| | | (B-1c) | — | 120 | 100 | — | 100 | — | 100 | 100 | 100 | 100 |
| | | (B-1d) | — | — | — | — | — | 100 | — | — | — | — |
| | | (B-2) | — | — | — | — | — | — | — | — | — | — |
| | (C) Epoxy | (C-1) | — | — | 20 | — | — | — | — | — | — | — |
| | compound | (C-2) | — | — | — | — | — | — | 20 | — | — | — |
| | | (C-3) | — | — | — | 20 | 20 | 20 | — | — | — | — |
| | | (C-4) | — | — | — | — | — | — | — | 20 | — | — |
| | | (C-5) | — | — | — | — | — | — | — | — | 20 | — |
| | | (C-6) | — | — | — | — | — | — | — | — | — | 20 |

| | | | | | | | | | | | |
|---|---|---|---|---|---|---|---|---|---|---|---|
| | Photocationic | 1.0 | 1.0 | 1.0 | 1.0 | 1.0 | 1.0 | 1.0 | 1.0 | 1.0 | 1.0 |
| | polymerization | | | | | | | | | | |
| | initiator | | | | | | | | | | |
| Evaluation | Tackiness | A | A | A | A | A | A | A | A | A | A |
| result | Crack resistance | 2 | 2 | 2 | 4 | 4 | 4 | 4 | 3 | 4 | 4 |
| | Developability | 2 | 3 | 3 | 4 | 4 | 4 | 4 | 4 | 4 | 3 |
| | Adhesion | B | B | A | A | A | A | A | A | A | A |
| | Resolution | 29 | 27 | 26 | 25 | 21 | 22 | 25 | 23 | 29 | 23 |
| | Aspect ratio | 12 | 13 | 13 | 14 | 17 | 16 | 14 | 15 | 12 | 15 |
| | Relative brightness | 102 | 105 | 106 | 107 | 112 | 111 | 107 | 110 | 102 | 110 |

TABLE 2

| | | | Exam- | Exam- | Exam- | Exam- | Exam- | Exam- | Exam- | Exam- | Exam- |
|---|---|---|---|---|---|---|---|---|---|---|---|
| | | | ple 11 | ple 12 | ple 13 | ple 14 | ple 15 | ple 16 | ple 17 | ple 18 | ple 19 |
| Composition | (A) Resin | (A-1) | 100 | 100 | 100 | 100 | 100 | 100 | — | — | — |
| (parts by mass) | | (A-2) | — | — | — | — | — | — | 100 | — | — |
| | | (A-3) | — | — | — | — | — | — | — | 100 | — |
| | | (A-4) | — | — | — | — | — | — | — | — | 100 |
| | (B) Oxetane | (B-1a) | — | — | — | — | — | — | — | — | — |
| | compound | (B-1b) | — | — | — | — | — | — | — | — | — |
| | | (B-1c) | 50 | 75 | 20 | 40 | 140 | 170 | 100 | 100 | 100 |
| | | (B-1d) | — | — | — | — | — | — | — | — | — |
| | | (B-2) | — | — | — | — | — | — | — | — | — |
| | (C) Epoxy compound | (C-1) | — | — | 90 | 70 | — | — | — | — | — |
| | | (C-2) | — | — | — | — | — | — | — | — | — |
| | | (C-3) | 10 | 15 | 10 | 10 | 10 | 10 | 20 | 20 | 20 |
| | | (C-4) | — | — | — | — | — | — | — | — | — |
| | | (C-5) | — | — | — | — | — | — | — | — | — |
| | | (C-6) | — | — | — | — | — | — | — | — | — |

| | | | | | | | | | | |
|---|---|---|---|---|---|---|---|---|---|---|
| | Photocationic | 1.0 | 1.0 | 1.0 | 1.0 | 1.0 | 1.0 | 1.0 | 1.0 | 1.0 |
| | polymerization | | | | | | | | | |
| | initiator | | | | | | | | | |
| Evaluation | Tackiness | A | A | A | A | B | C | A | A | A |
| result | Crack resistance | 2 | 3 | 4 | 4 | 4 | 4 | 4 | 4 | 4 |
| | Developability | 2 | 3 | 3 | 3 | 4 | 4 | 4 | 4 | 4 |
| | Adhesion | A | A | A | A | A | A | A | A | A |
| | Resolution | 25 | 23 | 29 | 25 | 27 | 30 | 22 | 26 | 30 |
| | Aspect ratio | 14 | 15 | 12 | 14 | 13 | 12 | 16 | 13 | 12 |
| | Relative brightness | 107 | 110 | 102 | 107 | 105 | 101 | 111 | 106 | 101 |

| | | | Comparative | Comparative | Comparative |
|---|---|---|---|---|---|
| | | | example 1 | example 2 | example 3 |
| Composition | (A) Resin | (A-1) | 100 | 100 | — |
| (parts by mass) | | (A-2) | — | — | — |
| | | (A-3) | — | — | — |
| | | (A-4) | — | — | — |
| | (B) Oxetane compound | (B-1a) | — | — | — |
| | | (B-1b) | — | — | — |
| | | (B-1c) | — | — | — |
| | | (B-1d) | — | — | — |
| | | (B-2) | 120 | — | — |
| | (C) Epoxy compound | (C-1) | — | 100 | — |
| | | (C-2) | — | — | — |
| | | (C-3) | — | — | — |
| | | (C-4) | — | — | — |
| | | (C-5) | — | — | — |
| | | (C-6) | — | — | — |

| | | | | |
|---|---|---|---|---|
| | Photocationic | 1.0 | 1.0 | — |
| | polymerization | | | |
| | initiator | | | |
| Evaluation | Tackiness | A | A | A |
| result | Crack resistance | 3 | 3 | 3 |
| | Developability | 2 | 1 | 4 |
| | Adhesion | B | A | A |
| | Resolution | 52 | 31 | 38 |
| | Aspect ratio | 7 | 11 | 9 |
| | Relative brightness | 77 | 100 | 92 |

### LIST OF REFERENCE SYMBOLS

1 member for radiation detector
2 scintillator panel
3 output substrate
4 substrate
5 barrier rib
6 phosphor layer
7 barrier film layer
8 photoelectric conversion layer
9 output layer
10 substrate
11 metal reflective layer
12 organic protective layer
13 phosphor
14 binder resin
15 inductor
16 insulation film
17 coil
18 resin layer
19 substrate
20 insulation film
21 magnetic material
22 mold resin
L1 height of barrier rib
L2 interval of adjacent barrier ribs
L3 bottom width of barrier rib
L4 top width of barrier rib
L5 middle width of barrier rib
T film thickness of insulation film
W pattern width of insulation film

1. A resin composition, comprising:
a (A) resin;
an (B) oxetane compound; and
a photocationic polymerization initiator,
wherein the (A) resin includes a resin having an alkali-soluble group, and
wherein the (B) oxetane compound includes a (B-1) compound having four or more oxetanyl groups.

2. The resin composition according to claim 1, wherein the (B-1) compound having four or more oxetanyl groups has a structure expressed by the following general formula (1). 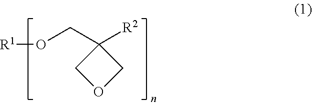
wherein:
R¹ represents an n-valent group having a siloxane bond,
R² represents a hydrogen atom or a monovalent organic group having 1 to 6 carbon atoms, and
“n” represents a range of from 4 to 30.

3. The resin composition according to claim 1, further comprising an (C) epoxy compound.

4. The resin compound according to claim 1, wherein at least any one of the (B) oxetane compound or the (C) epoxy compound has a polyalkylene glycol chain.

5. The resin composition according to claim 4, wherein the polyalkylene glycol chain has a number average molecular weight of from 300 to 4,000.

6. The resin composition according to claim 1, wherein a content of the (B-1) compound having four or more oxetanyl groups is from parts by mass to 160 parts by mass with respect to 100 parts by mass of the (A) resin.

7. A cured product obtained by curing the resin composition of claim 1.

8. A scintillator panel, comprising:
a substrate;
barrier ribs formed on the substrate; and
a phosphor layer formed in cells defined by the barrier ribs,
wherein the barrier ribs are made of the cured product of claim 7.

9. The scintillator panel according to claim 8, wherein the barrier ribs have a height L1 of 100 μm or more.

10. The scintillator panel according to claim 8, wherein an aspect ratio (L1/L5) of the height L1 of the barrier ribs with respect to a middle width L5 of the barrier ribs is 5.0 or more.

11. An inductor comprising an insulation film and a coil, wherein the insulation film is the cured product of claim 7.

12. The resin composition according to claim 1, wherein the alkali-soluble group includes at least one of a phenolic hydroxyl group, a carboxy group, a silanol group, and a sulfo group.

13. The resin composition according to claim 1, wherein the (B-1) compound having four or more oxetanyl groups has a structure expressed by the following general formula (2) 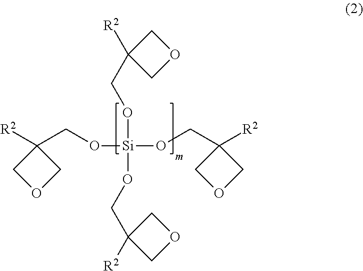
wherein:
R² represents a hydrogen atom or a monovalent organic group having 1 to 6 carbon atoms, and “m” is a repetition number and represents an integer of 1 or more.
